(19) United States
(12) Patent Application Publication
(10) Pub. No.: US 2016/0189786 A1
(43) Pub. Date: Jun. 30, 2016

(54) METHODS AND APPARATUS FOR REDUCING READ TIME FOR NONVOLATILE MEMORY DEVICES

(71) Applicant: SANDISK TECHNOLOGIES INC., Plano, TX (US)

(72) Inventors: Manabu Sakai, Yokohama (JP); Tayuka Ariki, Yokohama (JP)

(73) Assignee: SANDISK TECHNOLOGIES INC., Plano, TX (US)

(21) Appl. No.: 14/926,169

(22) Filed: Oct. 29, 2015

Related U.S. Application Data
(60) Provisional application No. 62/096,719, filed on Dec. 24, 2014.

(51) Int. Cl. G11C 16/26; G11C 16/16; G11C 11/56

(52) U.S. Cl. CPC G11C 16/26; G11C 11/5671; G11C 16/16

(57) ABSTRACT

A method for operating non-volatile memory device is provided. The method includes applying a first voltage level to a word line connected to a memory cell, applying a second voltage level to the word line for a first time period, performing a read operation on the memory cell during the first time period, and discharging the word line for a second time period to a third voltage level greater than or equal to about 1V. The method also includes performing an erase word line recovery on a plurality of blocks of memory cells during the erase operation, and prior to an erase phase. The erase word line recovery substantially discharges all word lines of the plurality of blocks of memory cells.

### CROSS REFERENCE TO RELATED APPLICATIONS

This application claims the benefit of Provisional Application 62/096,719, “ERASE PRE-RECOVERY FOR IMPROVED READ PERFORMANCE,” filed on Dec. 24, 2014, incorporated herein by reference in its entirety for all purposes.

### BACKGROUND

Semiconductor memory is widely used in various electronic devices such as cellular telephones, digital cameras, personal digital assistants, medical electronics, mobile computing devices, and non-mobile computing devices. Semiconductor memory may comprise non-volatile memory or volatile memory. A non-volatile memory allows information to be stored and retained even when the non-volatile memory is not connected to a source of power (e.g., a battery). Examples of non-volatile memory include flash memory (e.g., NAND-type and NOR-type flash memory) and Electrically Erasable Programmable Read-Only Memory (EEPROM).

A charge-trapping material can be used in non-volatile memory devices to store a charge which represents a data state. The charge-trapping material can be arranged vertically in a three-dimensional (3D) stacked memory structure. One example of a 3D memory structure is the Bit Cost Scalable (BiCS) architecture which comprises a stack of alternating conductive and dielectric layers. A memory hole is formed in the stack and a NAND string is then formed by filling the memory hole with materials including a charge-trapping layer to create a vertical column of memory cells. A straight NAND string extends in one memory hole. Control gates of the memory cells are provided by the conductive layers.

Some non-volatile memory devices are used to store two ranges of charges and, therefore, the memory cell can be programmed/erased between two ranges of threshold voltages that correspond to two data states: an erased state (e.g., data “1”) and a programmed state (e.g., data “0”). Such a device is referred to as a binary or two-state device.

A multi-state (or multi-level) non-volatile memory is implemented by identifying multiple, distinct allowed ranges of threshold voltages. Each distinct range of threshold voltages corresponds to a data state assigned a predetermined value for the set of data bits. The specific relationship between the data programmed into the memory cell and the ranges of threshold voltages depends upon the data encoding scheme adopted for the memory cells. For example, U.S. Pat. No. 6,222,762 and U.S. Patent Publication No. 2004/0255090 both describe various data encoding schemes for multi-state flash memory cells. Although multi-state non-volatile memory can store more data than binary non-volatile memory, the process for programming and verifying the programming can take longer for multi-state non-volatile memory.

### BRIEF DESCRIPTION OF THE DRAWINGS

Like-numbered elements refer to common components in the different figures.

FIG. 1 is a perspective view of a 3D stacked non-volatile memory device.

FIG. 2 is a functional block diagram of a memory device 200, which is an example of the 3D stacked non-volatile memory device 100 of FIG. 1.

FIG. 3A is a block diagram depicting software modules for programming one or more processors in a controller.

FIG. 3B is a block diagram depicting software modules for programming a state machine or other processor on a memory die.

FIG. 4A is a block diagram of a memory structure having two planes.

FIG. 4B is a top view of a portion of a block of memory cells.

FIG. 4C is a cross-sectional view of a portion of a block of memory cells.

FIG. 4D is a view of the select gate layers and word line layers.

FIG. 4E is a cross-sectional view of a vertical column of memory cells.

FIG. 5 is a block diagram depicting the connection of word lines to global control lines for multiple blocks of memory cells.

FIG. 6 is a timing diagram describing a read operation.

FIG. 7 is a timing diagram describing a read operation.

FIG. 8 is a timing diagram describing a read operation and an erase operation.

FIG. 9 is a flow chart describing an embodiment of a process for operating a non-volatile memory device.

FIG. 10 is a flow chart describing an embodiment of another process for operating a non-volatile memory device.

### DETAILED DESCRIPTION

Methods and apparatus for reducing read time of non-volatile memory devices are provided. An example method includes applying a first voltage level (e.g., 0V) to a word line connected to a memory cell, applying a second voltage level (e.g., a read pass voltage Vread) to the word line for a first time period, performing a read operation on the memory cell during the first time period, and discharging the word line for a second time period to a third voltage level greater than or equal to about 1V. The discharge occurs during a reduced read word line recovery time shorter than a time required to fully discharge the word line. The method also includes performing an erase word line recovery on a plurality of blocks of memory cells during the erase operation, and prior to an erase phase. The erase word line recovery substantially discharges all word lines of the plurality of blocks of memory cells.

The following discussion provides details of one example of a suitable structure for a memory devices that can implement the proposed technology.

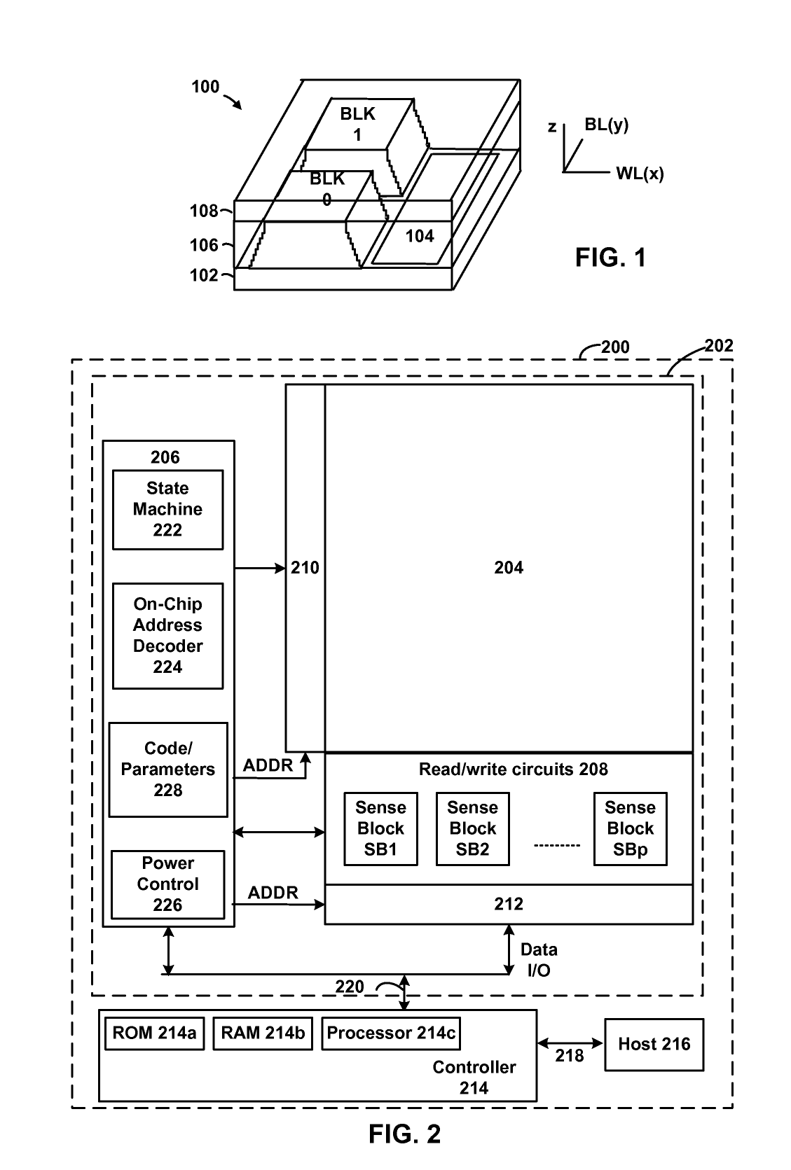

FIG. 1 is a perspective view of a three dimensional (3D) stacked non-volatile memory device 100, which includes a substrate 102. On and above substrate 102 are example blocks BLK0 and BLK1 of memory cells (non-volatile storage elements).

Also on substrate 102 is peripheral area 104 with support circuits for use by blocks BLK0 and BLK1. Substrate 102 also can carry circuits under the blocks, along with one or more lower metal layers which are patterned in conductive paths to carry signals of the circuits.

Blocks BLK0 and BLK1 are formed in an intermediate region 106 of memory device 100. In an upper region 108 of memory device 100, one or more upper metal layers are patterned in conductive paths to carry signals of the circuits. Each of blocks BLK0 and BLK1 includes a stacked area of memory cells, where alternating levels of the stack represent word lines. Although two blocks BLK0 and BLK1 are depicted as an example, additional blocks can be used, extending in the x- and/or y-directions.

In one example implementation, the length of the plane in the x-direction, represents a direction in which signal paths for word lines extend (a word line or SGD line direction), and the width of the plane in the y-direction, represents a direction in which signal paths for bit lines extend (a bit line direction). The z-direction represents a height of the memory device.

FIG. 2 is a functional block diagram of an example memory device 200, which is an example of the 3D stacked non-volatile memory device 100 of FIG. 1. The components depicted in FIG. 2 are electrical circuits. Memory device 200 includes one or more memory die 202. Each memory die 202 includes a three dimensional memory structure 204 of memory cells (such as, for example, a 3D array of memory cells), control circuitry 206, and read/write circuits 208. In other embodiments, a two dimensional array of memory cells can be used.

Memory structure 204 is addressable by word lines via a row decoder 210 and by bit lines via a column decoder 212. Read/write circuits 208 include multiple sense blocks SB1, SB2, . . . , SBp (sensing circuitry) and allow a page of memory cells to be read or programmed in parallel. In some systems, a controller 214 is included in the same memory device 200 (e.g., a removable storage card) as the one or more memory die 202. However, in other systems, controller 214 can be separated from memory die 202.

In some embodiments, one controller 214 will communicate with multiple memory die 202. In other embodiments, each memory die 202 has its own controller. Commands and data are transferred between a host 216 and controller 214 via a data bus 218, and between controller 214 and the one or more memory die 202 via lines 220. In one embodiment, memory die 202 includes a set of input and/or output (I/O) pins that connect to lines 220.

Memory structure 204 may include one or more arrays of memory cells including a 3D array. Memory structure 204 may include a monolithic three dimensional memory structure in which multiple memory levels are formed above (and not in) a single substrate, such as a wafer, with no intervening substrates. Memory structure 204 may include any type of non-volatile memory that is monolithically formed in one or more physical levels of arrays of memory cells having an active area disposed above a silicon substrate. Memory structure 204 may be in a non-volatile memory device having circuitry associated with the operation of the memory cells, whether the associated circuitry is above or within the substrate.

Control circuitry 206 cooperates with read/write circuits 208 to perform memory operations (e.g., erase, program, read, and others) on memory structure 204, and includes a state machine 222, an on-chip address decoder 224, and a power control module 226. State machine 222 provides chip-level control of memory operations. Code and parameter storage 228 may be provided for storing operational parameters and software. In one embodiment, state machine 222 is programmable by the software stored in code and parameter storage 228. In other embodiments, state machine 222 does not use software and is completely implemented in hardware (e.g., electronic circuits).

On-chip address decoder 224 provides an address interface between addresses used by host 216 or memory controller 214 to the hardware address used by decoders 210 and 212. Power control module 226 controls the power and voltages supplied to the word lines and bit lines during memory operations. Power control module 226 can include drivers for word line layers (discussed below) in a 3D configuration, select transistors (e.g., SGS and SGD transistors, described below) and source lines. Power control module 226 may include charge pumps for creating voltages. Sense blocks SB1, SB2, . . . , SBp include bit line drivers. An SGS transistor is a select gate transistor at a source end of a NAND string, and an SGD transistor is a select gate transistor at a drain end of a NAND string.

Any one or any combination of control circuitry 206, state machine 222, decoders 224/210/212, code and parameter storage 228, power control module 226, sense blocks SB1, SB2, . . . , SBp, read/write circuits 208, and controller 214 can be considered one or more control circuits that performs the functions described herein.

The (on-chip or off-chip) controller 214 may include storage devices (memory) such as ROM 214a and RAM 214b and a processor 214c. Storage devices ROM 214a and RAM 214b include code such as a set of instructions, and processor 214c is operable to execute the set of instructions to provide the functionality described herein. Alternatively or additionally, processor 214c can access code from a storage device in memory structure 204, such as a reserved area of memory cells connected to one or more word lines.

Multiple memory elements in memory structure 204 may be configured so that they are connected in series or so that each element is individually accessible. By way of non-limiting example, flash memory devices in a NAND configuration (NAND flash memory) typically contain memory elements connected in series. A NAND string is an example of a set of series-connected memory cells and select gate transistors.

A NAND flash memory array may be configured so that the array is composed of multiple NAND strings of which a NAND string is composed of multiple memory cells sharing a single bit line and accessed as a group. Alternatively, memory elements may be configured so that each element is individually accessible, e.g., a NOR memory array. NAND and NOR memory configurations are exemplary, and memory cells may be otherwise configured.

The memory cells may be arranged in the single memory device level in an ordered array, such as in a plurality of rows and/or columns. However, the memory elements may be arrayed in non-regular or non-orthogonal configurations, or in structures not considered arrays.

A three dimensional memory array is arranged so that memory cells occupy multiple planes or multiple memory device levels, thereby forming a structure in three dimensions (i.e., in the x, y and z directions, where the z direction is substantially perpendicular and the x and y directions are substantially parallel to the major surface of the substrate).

As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in the y direction) with each column having multiple memory cells. The vertical columns may be arranged in a two dimensional configuration, e.g., in an x-y plane, resulting in a three dimensional arrangement of memory cells, with memory cells on multiple vertically stacked memory planes. Other configurations of memory elements in three dimensions can also constitute a three dimensional memory array.

By way of non-limiting example, in a three dimensional NAND memory array, the memory elements may be coupled together to form a vertical NAND string that traverses across multiple horizontal memory device levels. Other three dimensional configurations can be envisioned wherein some NAND strings contain memory elements in a single memory level and other strings contain memory elements which span through multiple memory levels. Three dimensional memory arrays may also be designed in a NOR configuration and in a ReRAM configuration.

A person of ordinary skill in the art will recognize that this technology is not limited to a single specific memory structure, but covers many relevant memory structures within the spirit and scope of the technology as described herein and as understood by one of ordinary skill in the art.

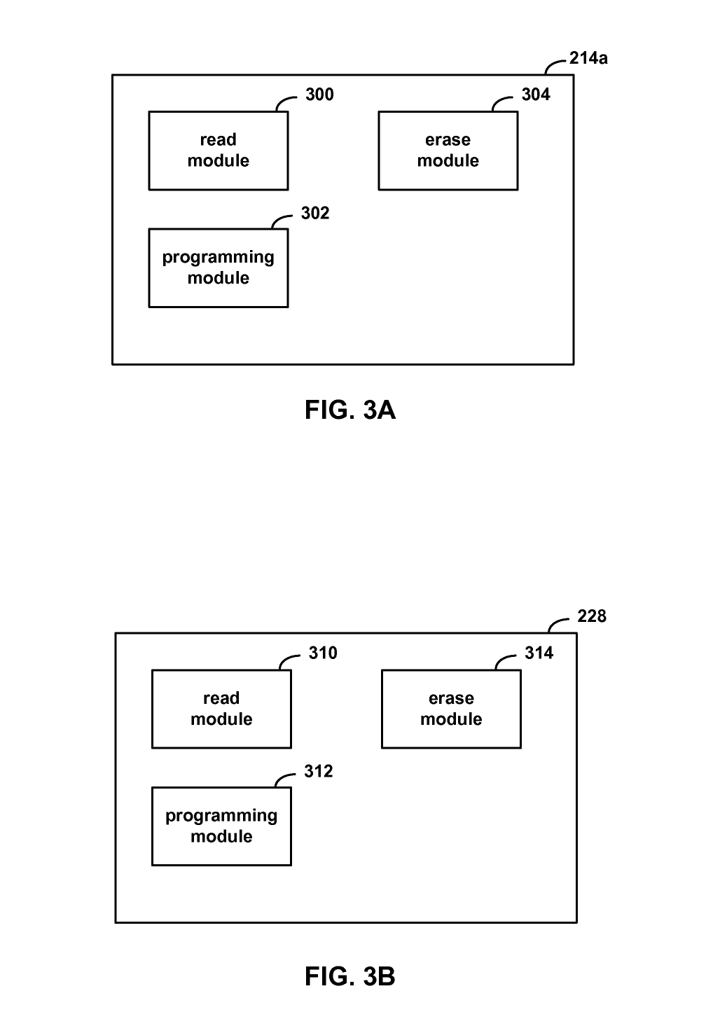

FIG. 3A is a block diagram depicting software modules for programming one or more processors in controller 214 of FIG. 2. FIG. 3A depicts read module 300, programming module 302, and erase module 304 being stored in ROM 214a. These software modules also can be stored in RAM or memory die 202. Read module 300 includes software that programs processor(s) 214c to perform read operations. Programming module 302 includes software that programs processor(s) 214c to perform programming operations (including verification of programming). Erase module 304 includes software that programs processor(s) 214c to perform erase operations. Based on the software, controller 214 instructs memory die 202 to perform memory operations.

FIG. 3B is a block diagram depicting software modules for programming state machine 222 of FIG. 2 (or other processor on memory die 202). FIG. 3B depicts read module 310, programming module 312, and erase module 314 being stored in code and parameter storage 228. These software modules can also be stored in RAM or in memory structure 204 of FIG. 2. Read module 310 includes software that programs state machine 222 to perform read operations. Programming module 302 includes software that programs state machine 222 to perform programming operations (including verification of programming). Erase module 304 includes software that programs state machine 222 to perform erase operations. Alternatively, state machine 222 (which is an electronic circuit) can be completely implemented with hardware so that no software is needed to perform these functions.

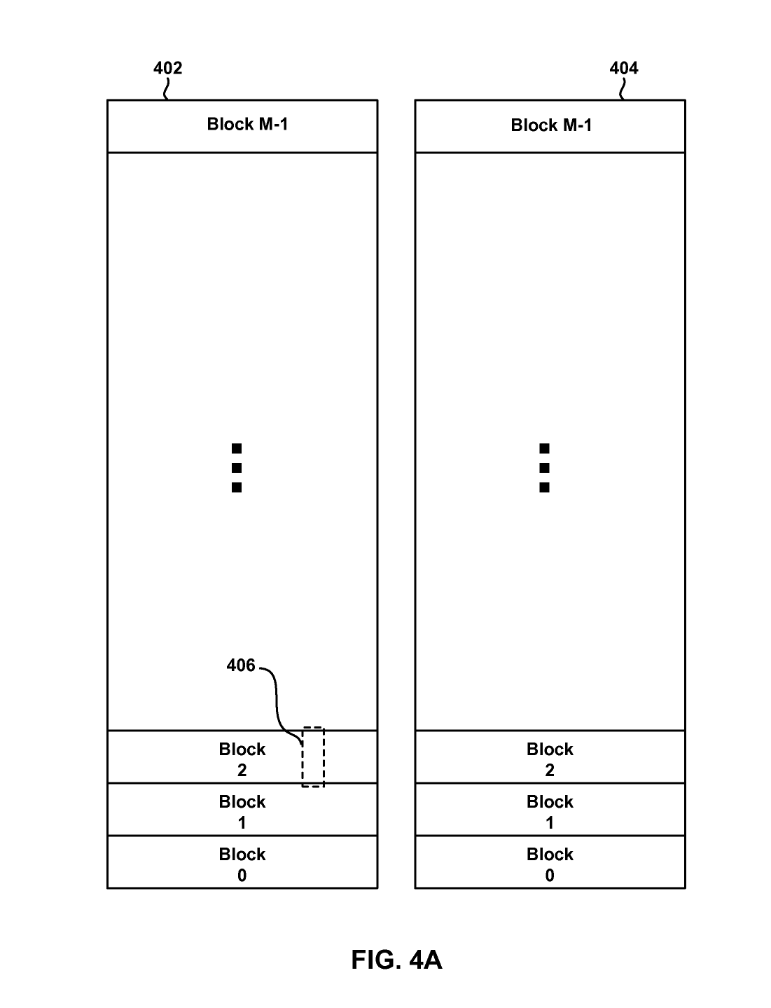

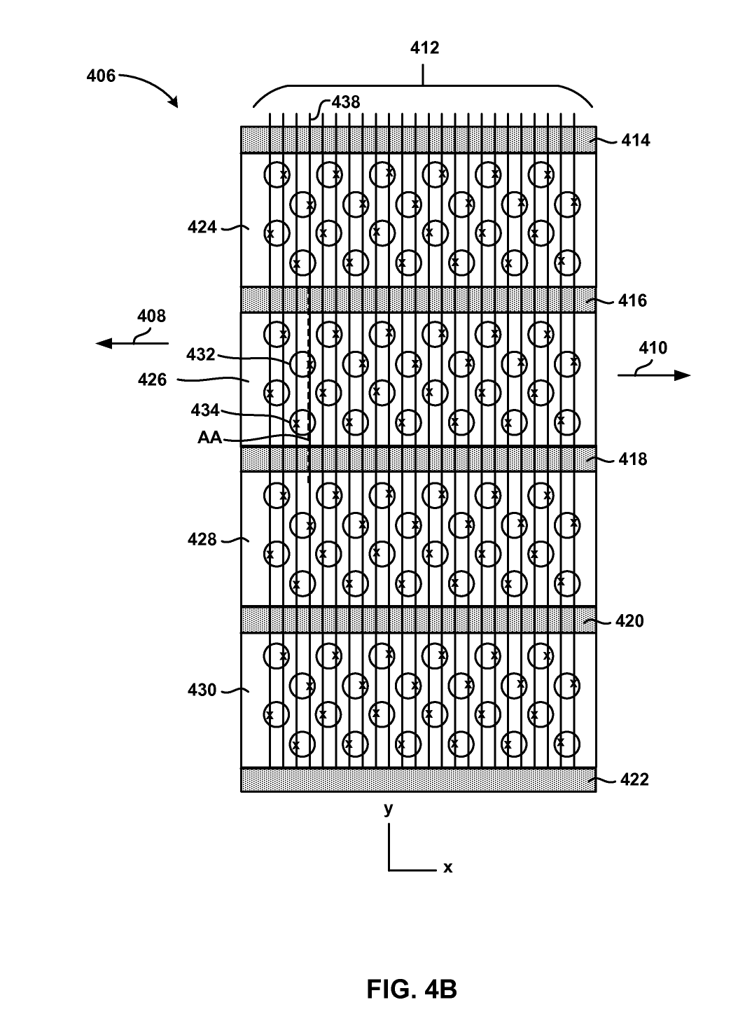

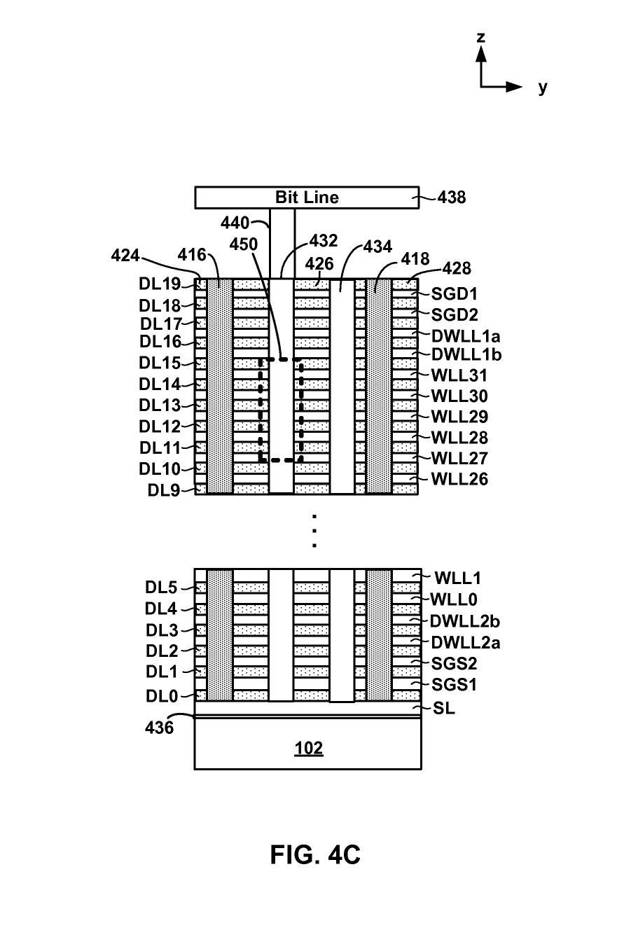

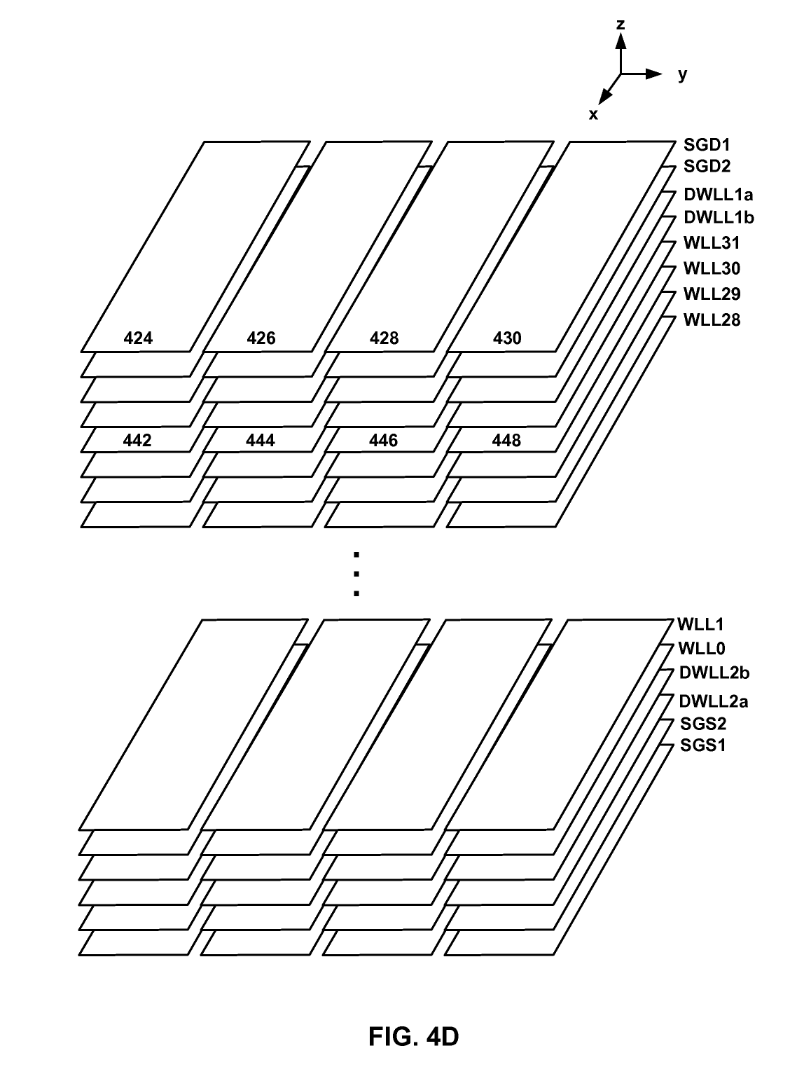

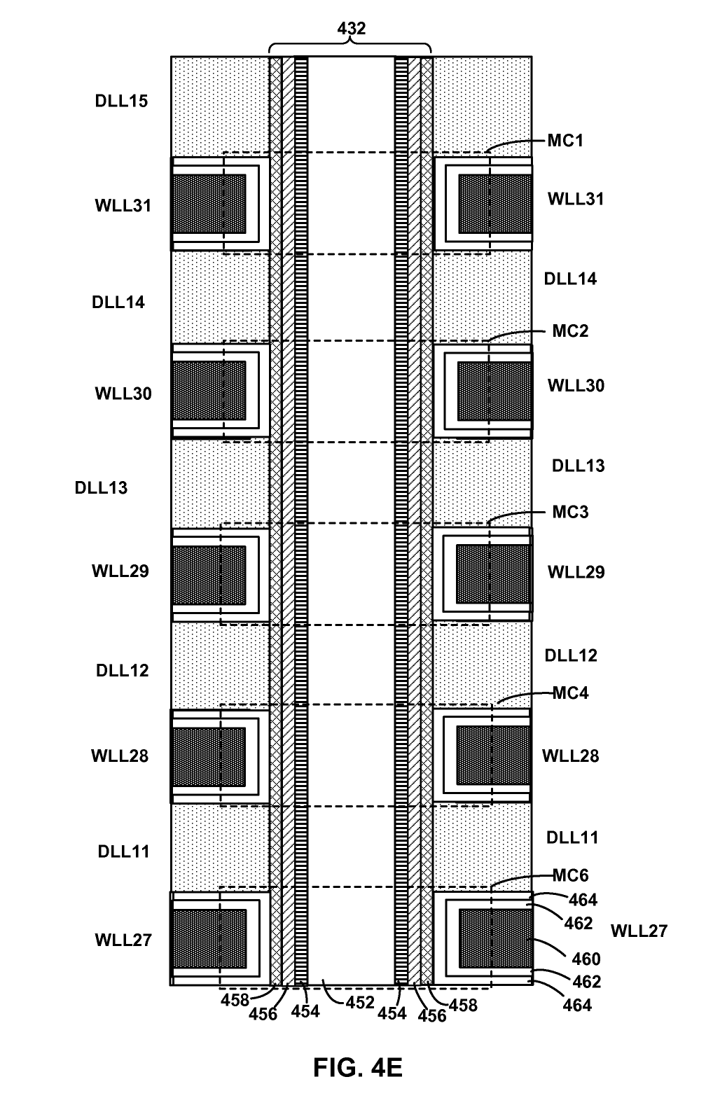

FIG. 4A is a block diagram explaining one example organization of memory structure 204, which is divided into two planes 402 and 404. Each plane is then divided into M blocks. In one example, each plane has about 2000 blocks. However, different numbers of blocks and planes can also be used.

FIGS. 4B-4E depict an example 3D NAND structure. FIG. 4B is a block diagram depicting a top view of a portion of one block from memory structure 204. The portion of the block depicted in FIG. 4B corresponds to portion 406 in block 2 of FIG. 4A. The block depicted in FIG. 4B extends in the direction of arrow 408 and in the direction of arrow 410. In one embodiment, the memory array will have 48 layers. Other embodiments have less than or more than 48 layers. However, FIG. 4B only shows the top layer.

FIG. 4B depicts a plurality of circles that represent the vertical columns. Each of the vertical columns include multiple select transistors and multiple memory cells. In one embodiment, each vertical column implements a NAND string. More details of the vertical columns are provided below. Because the block depicted in FIG. 4B extends in the direction of arrow 408 and in the direction of arrow 410, the block includes more vertical columns than depicted in FIG. 4B

FIG. 4B also depicts a set of bit lines 412. FIG. 4B shows twenty four bit lines because only a portion of the block is depicted. In other embodiments, more than twenty four bit lines are connected to vertical columns of the block. Each of the circles representing vertical columns has an “x” to indicate its connection to one bit line.

The block depicted in FIG. 4B includes a set of local interconnects 414, 416, 418, 420 and 422 that connect the various layers to a source line below the vertical columns. Local interconnects 414, 416, 418, 420 and 422 also serve to divide each layer of the block into four regions. For example, the top layer depicted in FIG. 4B is divided into regions 424, 426, 428 and 430.

In the layers of the block that implement memory cells, the four regions are referred to as word line fingers that are separated by the local interconnects. In one embodiment, the word line fingers on a common level of a block connect together at the end of the block to form a single word line. In another embodiment, the word line fingers on the same level are not connected together.

In one example implementation, a bit line only connects to one vertical column in each of regions 424, 426, 428 and 430. In that implementation, each block has sixteen rows of active columns and each bit line connects to four rows in each block. In one embodiment, all of four rows connected to a common bit line are connected to the same word line (via different word line fingers on the same level that are connected together). Therefore, the system uses the source select lines and the drain select lines to choose one (or another subset) of the four to be subjected to a memory operation (program, verify, read, and/or erase).

Although FIG. 4B shows each region having four rows of vertical columns, four regions and sixteen rows of vertical columns in a block, those exact numbers are an example implementation. Other embodiments may include more or less regions per block, more or less rows of vertical columns per region and more or less rows of vertical columns per block.

FIG. 4B also shows the vertical columns being staggered. In other embodiments, different patterns of staggering can be used. In some embodiments, the vertical columns are not staggered.

FIG. 4C depicts a portion of an embodiment of three dimensional memory structure 204 showing a cross-sectional view along line AA of FIG. 4B. This cross-sectional view cuts through vertical columns 432 and 434 and region 426 (see FIG. 4B). The structure of FIG. 4C includes two drain select layers (SGD1 and SGD1), two source select layers (SGS1 and SGS2), four dummy word line layers (DWLL1a, DWLL1b, DWLL2a and DWLL2b), and thirty two word line layers (WLL0-WLL31) for connecting to data memory cells. Other embodiments can implement more or less than two drain select layers, more or less than two source select layers, more or less than four dummy word line layers, and more or less than thirty two word line layers.

Vertical columns 432 and 434 are depicted protruding through the drain select layers, source select layers, dummy word line layers and word line layers. In one embodiment, each of vertical columns 432 and 434 comprises a NAND string. An insulating film 436 is disposed on substrate 102, a source line SL is disposed on insulating film 436, and vertical columns 432 and 434 are disposed on source line SL. Vertical column 432 is connected to Bit Line 438 via connector 440. Local interconnects 416 and 418 are also depicted.

For ease of reference, drain select layers (SGD1 and SGD1), source select layers (SGS1 and SGS2), dummy word line layers (DWLL1a, DWLL1b, DWLL2a and DWLL2b), and word line layers (WLL0-WLL31) collectively are referred to as the conductive layers. In one embodiment, the conductive layers are made from a combination of TiN and Tungsten. In other embodiments, other materials can be used to form the conductive layers, such as doped polysilicon, metal such as Tungsten or metal silicide. In some embodiments, different conductive layers can be formed from different materials.

Between conductive layers are dielectric layers DL0-DL19. For example, dielectric layers DL10 is above word line layer WLL26 and below word line layer WLL27. In one embodiment, the dielectric layers are made from SiO₂. In other embodiments, other dielectric materials can be used to form the dielectric layers.

The word line layer WLL0-WLL31 connect to memory cells (also called data memory cells). Dummy word line layers DWLL1a, DWLL1b, DWLL2a and DWLL2b connect to dummy memory cells. A dummy memory cell, also referred to as a non-data memory cell, does not store user data, whereas a data memory cell is eligible to store user data. Thus, data memory cells may be programmed. Drain select layers SGD1 and SGD1 are used to electrically connect and disconnect NAND strings from bit lines. Source select layers SGS1 and SGS2 are used to electrically connect and disconnect NAND strings from the source line SL.

FIG. 4D depicts a perspective view of the conductive layers (SGD1, SGD1, SGS1, SGS2, DWLL1a, DWLL1b, DWLL2a, DWLL2b, and WLL0-WLL31) for the block that is partially depicted in FIG. 4C. As mentioned above with respect to FIG. 4B, local interconnects 414, 416, 418, 420 and 422 break up each conductive layers into four regions. For example, drain select gate layer SGD1 (the top layer) is divided into regions 424, 426, 428 and 430. Similarly, word line layer WLL31 is divided into regions 442, 444, 446 and 448. For word line layers (WLL0-WLL31), the regions are referred to as word line fingers; for example, word line layer WLL31 is divided into word line fingers 442, 444, 446 and 448.

FIG. 4E depicts a cross sectional view of region 450 of FIG. 4C that includes a portion of vertical column 432. In one embodiment, the vertical columns are round and include four layers. In other embodiments, however, more or less than four layers can be included and other shapes can be used. In one embodiment, vertical column 432 includes an inner core layer 452 that is made of a dielectric, such as SiO₂. Other materials can also be used. Surrounding inner core 452 is vertical polysilicon channel 454. Materials other than polysilicon can also be used. Note that vertical polysilicon channel 454 connects to the bit line. Surrounding vertical polysilicon channel 454 is a tunneling dielectric 456. In one embodiment, tunneling dielectric 456 has an oxide-nitride-oxide (ONO) structure. Surrounding tunneling dielectric 456 is charge trapping layer 458, such as (for example) a specially formulated silicon nitride that increases trap density.

FIG. 4E depicts dielectric layers DLL11, DLL12, DLL13, DLL14 and DLL15, as well as word line layers WLL27, WLL28, WLL29, WLL30, and WLL31. Each of the word line layers includes a word line region 460 surrounded by an aluminum oxide layer 462, which is surrounded by a blocking oxide (SiO₂) layer 464. The physical interaction of the word line layers with the vertical column forms the memory cells. Thus, a memory cell, in one embodiment, comprises vertical polysilicon channel 454, tunneling dielectric 456, charge trapping layer 458, blocking oxide layer 464, aluminum oxide layer 462 and word line region 460.

For example, word line layer WLL31 and a portion of vertical column 432 comprise a memory cell MC1. Word line layer WLL30 and a portion of vertical column 432 comprise a memory cell MC2. Word line layer WLL29 and a portion of vertical column 432 comprise a memory cell MC3. Word line layer WLL28 and a portion of vertical column 432 comprise a memory cell MC4. Word line layer WLL27 and a portion of vertical column 432 comprise a memory cell MC5. In other architectures, a memory cell may have a different structure; however, the memory cell would still be the storage unit.

When a memory cell is programmed, electrons are stored in a portion of charge trapping layer 458 which is associated with the memory cell. These electrons are drawn into charge trapping layer 458 from vertical polysilicon channel 454, through tunneling layer 458, in response to an appropriate voltage on word line region 460. The threshold voltage (Vth) of a memory cell is increased in proportion to the amount of stored charge. During an erase operation, the electrons return to the channel or holes recombine with electrons.

In an embodiment, memory cells are erased by raising the channel to an erase voltage Vera (e.g., 20-24 volts) for a sufficient period of time and grounding the word lines of a selected block while source and bit lines are floating. In blocks that are not selected to be erased, word lines are floated. Due to capacitive coupling, the unselected word lines, bit lines, select lines, and common source line are also raised to a significant fraction of erase voltage Vera, thereby impeding erase on blocks that are not selected to be erased.

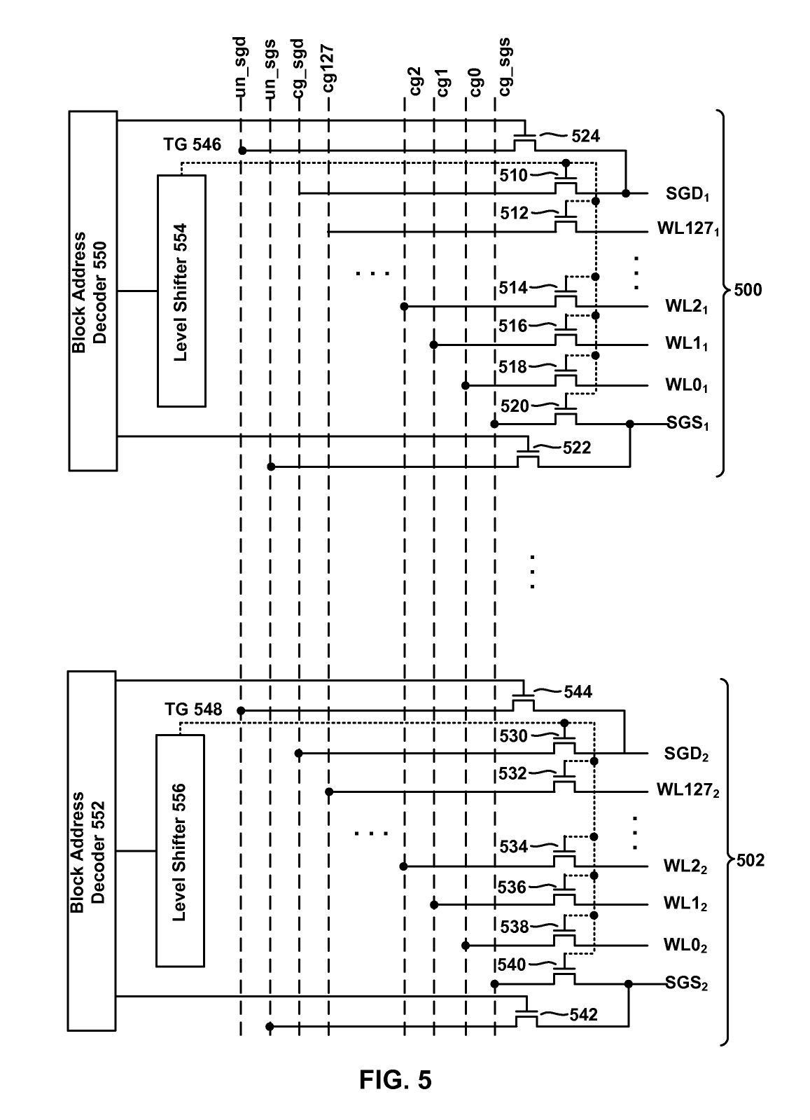

FIG. 5 is a block diagram depicting the connection of word lines to global control lines from multiple blocks of memory cells. In this example, each block includes assumes 128 word lines (and 128 data memory cells in a NAND string). There are 132 global control lines including un_sgd, un_sgs, cg_sgd, cg127, . . . cg2, cg1, cg0, cg_sgs (depicted as dashed lines to make it easier to read). These global control lines receive voltages from charge pumps or other voltage providing circuits and transport those voltages to the word lines for selected blocks of memory cells.

For example, cg0 can be selectively connected to WL0 of any block, cg1 can be selectively connected to WL1 of any block, . . . cg127 can be selectively connected to WL127 of any block of memory cells. The signals cg_sgs and cg_sgd connect to sgs and sgd, respectively, of any selected block. The signals un_sgd and un sgs are used to prevent unselected blocks from conducting any current, as will be discussed below.

Block 500 includes word lines WL0₁, WL1₁, WL2₁, . . . WL127₁, and block 502 includes word lines WL0₂, WL1₂, WL2₂, . . . WL127₂. Note that the memory system may have more than two blocks (as implied by the ellipsis). However, two blocks are depicted to make the drawing readable. Each of the blocks include a set of word line switches that interface between the word lines (and control lines SGS and SGD) and the global control lines.

For example, block 500 includes word line switches 510, 512, . . . , 514, 516, 518 and 520. Block 502 includes word line switches 530, 532, . . ., 534, 536, 538 and 540. In one embodiment, each of the word line switches are transistors. In other embodiments, other types of switches can be used. The drain of each of the word line switches are connected to the respective word line, and the source of the respective word line switches are connected to the respective global control lines.

For example, word line switch 514 has its source connected to cg2 and its drain connected to WL2₁. The gates of the word line switches 510-520 of block 500 are all connected to the same gate line TG 546. The gates of word line switches 530-540 of block 502 are all connected to the same gate line TG 548. Gate line TG 546 and gate line TG 548 are depicted as dotted lines only for purposes of making the drawing easier to read.

Row decoders 210 (FIG. 2) include Block Address Decoders 550 and 552 depicted in FIG. 5, which decode whether their respective blocks are selected for a memory operation (e.g., read, program, erase). If so, the respective Block Address Decoder 550 and 552 will instruct the connected Level Shifters 554 and 556, respectively, to generate the appropriate signals on the TG line.

If block 500 is selected for erase, then appropriate voltages will be placed on the global control lines (e.g., cg0-cg127) and Level Shifter 554 asserts a HIGH voltage on TG 546 so that word line switches 510-520 turn ON and connect word lines WL0₁, WL1₁, WL2₁, . . . WL127₁ to the global control lines cg0-cg127. If block 502 is not selected for being erased, then Level Shifter 556 will assert a LOW voltage on TG line 548 so that the word line switches 530-540 all remain OFF and word lines WL0₂, WL1₂, WL2₂, . . . WL127₂ are floated (and electrically isolated from the global control lines (cg0-cg127).

FIG. 5 shows transistor 522 switching between un_sgs and the signal SGS₁. This is used in a read process and a program process when block 500 is not selected, to force zero volts on SGS₁. Similarly, when block 500 is not selected during read and program processes, transistor 524 is turned ON so that zero volts can be applied from un_sgd to SGD₁. Transistor 544 performs the same function for block 502 that transistor 524 performs for block 500. Transistor 542 performs the same function for block 502 that transistor 522 performs for block 500.

During a read operation, a control gate voltage (e.g., Vcgrv) is provided on a selected word line which is associated with a selected memory cell. Vcgrv may be between about 0V and about 6V, although other values may be used. A read pass voltage, Vread, can be applied to unselected word lines associated in the same block. The magnitude of Vread is sufficient to turn ON the unselected memory cells. Vread may be between about 6V and about 8V, although other values may be used.

For example, if a memory cell connected to WL1i in block 500 is to be read, read voltage Vcgrv is asserted on global control line cg1, and read pass voltage Vread is asserted on global control lines cg0 and cg2 . . . cg127, and Level Shifter 554 asserts a HIGH voltage on TG 546 so that word line switches 510-520 turn ON and connect word lines WL0₁, WL1₁, WL2₁, . . . WL127₁ to global control lines cg0-cg127.

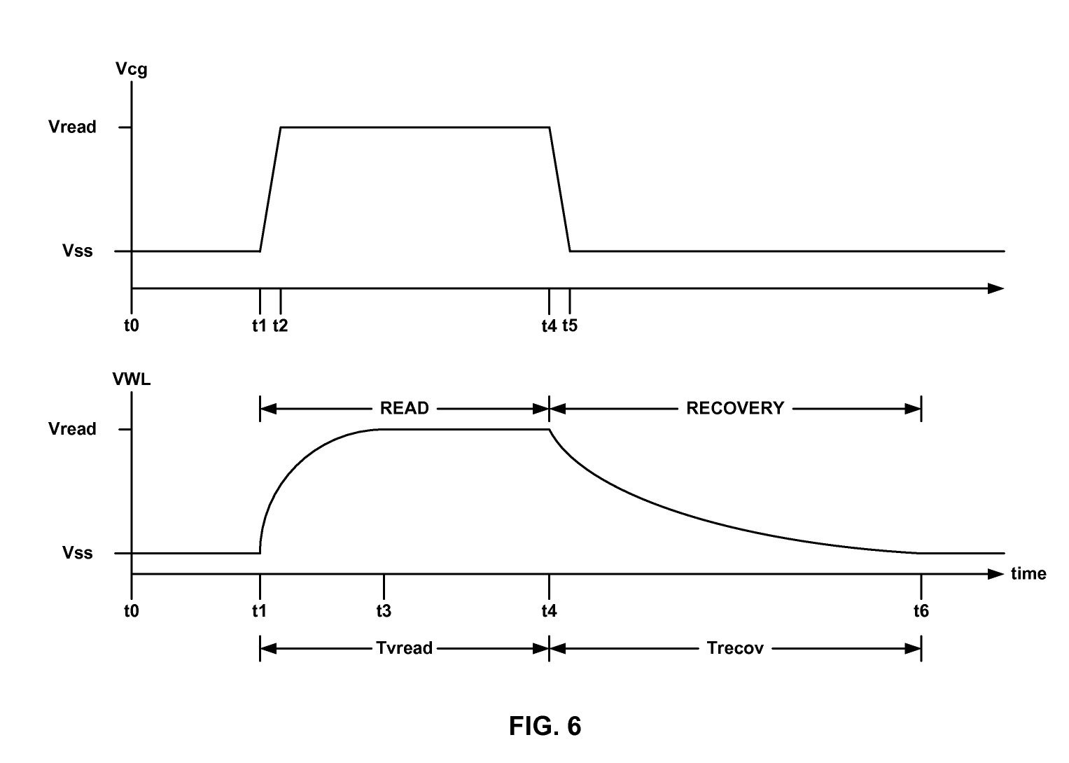

FIG. 6 illustrates a diagram of example control gate (e.g., cg0) voltage Vcg of an unselected word line (e.g., WL0₁) voltage VWL versus time during a read operation that includes a read phase and a read word line recovery phase. At time t0, prior to the read operation, word line voltage Vcg=VWL=Vss (e.g., 0V). At time t=t1, control gate voltage Vcg begins increasing, and at time t=t2, control gate voltage Vcg=read pass voltage Vread. Prior to time t=t1, Level Shifter 554 asserts a HIGH voltage on TG 546 so that word line switches 510-520 turn ON and connect word lines WL0₁, WL1₁, WL2₁, . . . WL127ᵢ to global control lines cg0-cg127.

As a result of various parasitic resistances and capacitances, word line WL0₁ ramps up from Vss to Vread between t=t1 and t=t3. The time interval (t3−t1) may be on the order of about 10 μsec. From t=t3 to t=t4, word line voltage VWL=Vread. The read phase occurs during the read time Tvread=(t4−t1), which may be on the order of about 30 μsec.

At time t=t4, control gate voltage Vcg begins decreasing, and at time t=t5, control gate voltage Vcg=Vss. Word line switches 510-520 remain ON and word lines

WL0₁, WL1₁, WL2₁, . . . WL127₁ remain connected to global control lines cg0-cg127. As a result of various parasitic resistances and capacitances, word line voltage VWL begins decreasing from Vread towards Vss. The read word line recovery phase occurs during the read word line recovery time Trecov=(t6−t4), which may be on the order of about between about 10 μsec and about 20 μsec. In some implementations, word line voltage VWL need not decrease completely to Vss during the read word line recovery operation. For example, if Vss=0V, read word line recovery may discharge VWL to about 100 mV.

For improved read performance, it is desirable to reduce read word line recovery time Trecov. One way to reduce read word line recovery time Trecov is to use multiple transistors for each word line switch (e.g., word line switches 510-520 and 530-540). That is, if each word line switch is replaced with multiple word line switches in parallel, the resistance from each word line to the corresponding global control line (e.g., cg0-cg127) is reduced, and therefore the time required to discharge each word line decreases. Although this technique would reduce read word line recovery time Trecov, the technique requires a much larger area to implement the numerous word line switches.

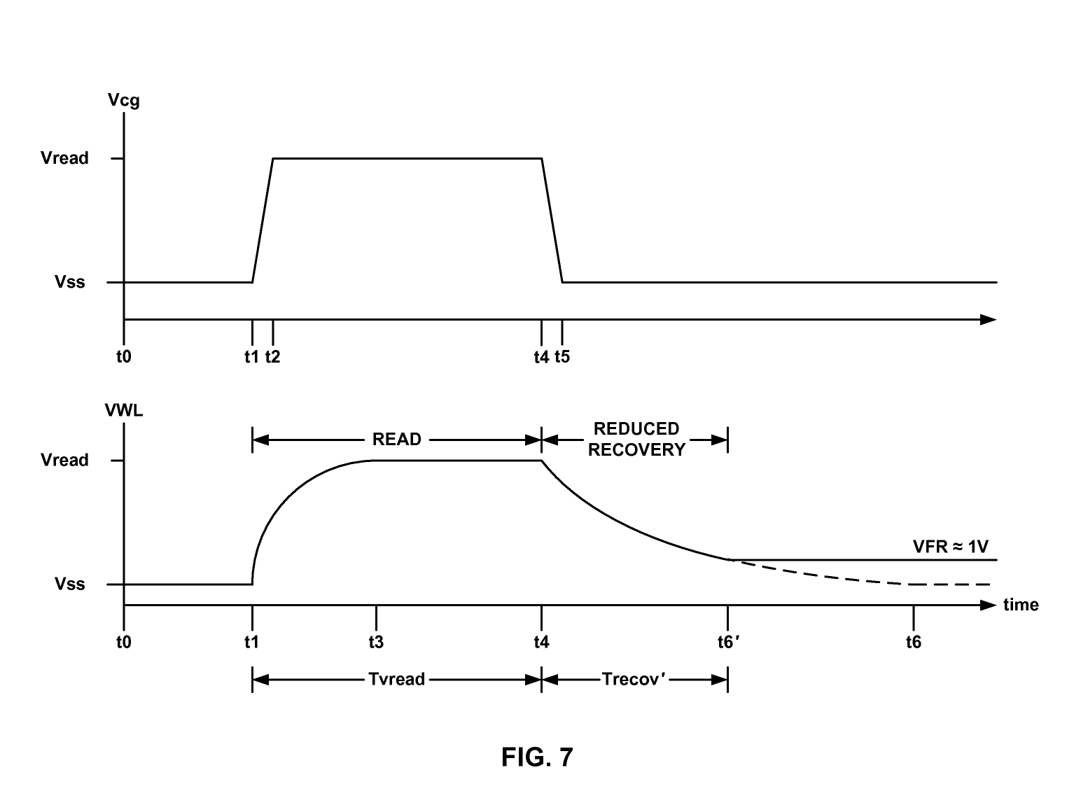

Methods are described for providing a reduced read word line recovery time Trecov′ without requiring use of multiple word line switches in parallel. In particular, the reduced read word line recovery time Trecov′ terminates with a non-zero word line voltage, VFR. For example, as depicted in FIG. 7, the reduced read word line recovery time Trecov′ may terminate with a word line voltage of VFR of greater than or equal to about 1V, although other VFR values may be used. For simplicity, the remaining discussion will assume that VFR=1V.

In the illustrated example, the reduced read word line recovery time Trecov′=(t6′−t4), which is shorter than the read word line recovery time Trecov=(t6−t4) of FIG. 6. In some embodiments, the reduced read word line recovery time Trecov′ may be between about 5 μsec to about 10 μsec, although other values may be used. Persons of ordinary skill in the art will understand that a reduced read word line recovery time also may be used during verify operations.

As described above, memory cells are erased by raising the channel to an erase voltage Vera (e.g., 20-24 volts) for a sufficient period of time and grounding the word lines of a selected block while source and bit lines are floating. In blocks that are not selected to be erased, word lines are floated. Due to capacitive coupling, the unselected word lines, bit lines, select lines, and common source line are also raised by around Vera, thereby impeding erase on blocks that are not selected to be erased.

As described above, at the end of a read operation with a reduced read word line recovery time Trecov′, word lines coupled to unselected memory cells have a voltage of VFR=1V. Thus, if an unselected word line was discharged to VFR during the prior read operation, in an erase operation performed on a different block, the gate-to-drain voltage of the word line switch connected to the unselected word line would be (Vera+VFR). If VFR=1V, the word line switches connected to unselected word lines are subjected to a larger gate-to-drain voltage by about 1V, which may damage the word line switches more. To avoid this potential damage, an erase word line recovery step is added to erase operations that follow a read operation. Persons of ordinary skill in the art will understand that an erase word line recovery step also may be added to erase operations that follow a program verify operation.

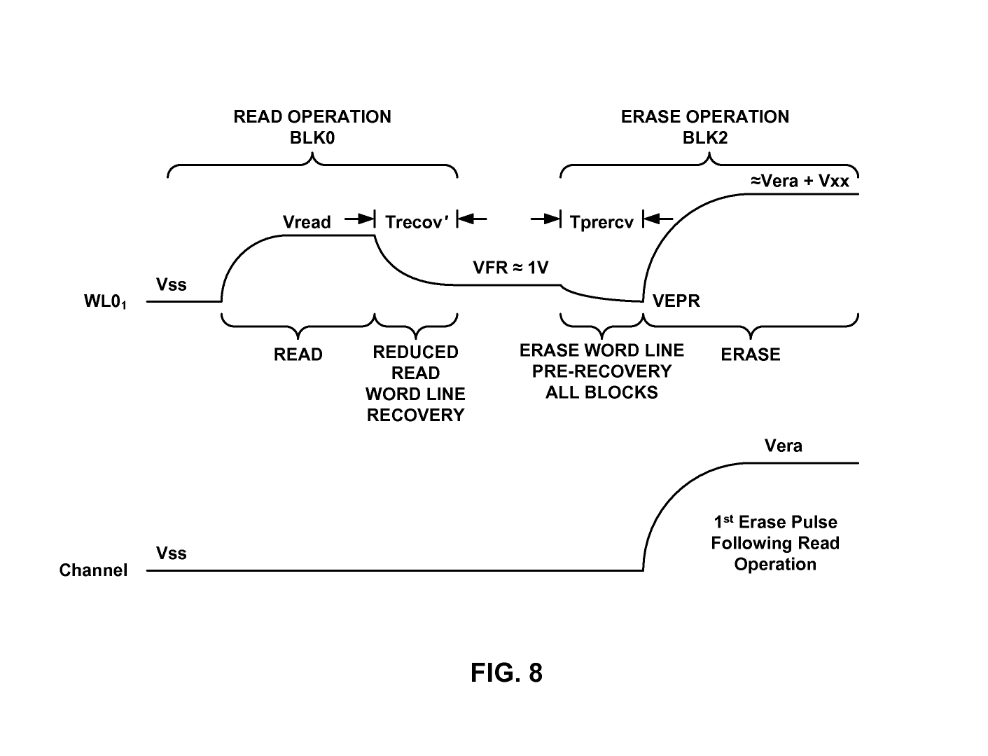

FIG. 8 illustrates an example of an erase word line recovery operation. In particular, FIG. 8 illustrates channel voltages and word line voltages for a memory device that includes multiple blocks of memory cells BLK0, BLK1, BLK2, . . . . In response to a user command, a read operation is performed on a memory cell coupled to a word line in bock BLK0 (e.g., word line WL2₁), with all other word lines in block BLK0 coupled to unselected memory cells, and then an erase operation is performed on the memory cells in block BLK2. FIG. 8 depicts the word line voltage of an unselected word line (e.g., WL0₁) in block BLK0.

The read operation includes a read phase and a reduced read word line recovery phase. During the read phase, word line WL0₁ starts at Vss, and then ramps up to read pass voltage Vread. During the reduced read word line recovery phase, word line WL0₁ discharges to VFR during a reduced read word line recovery time Trecov′. As described above, in an embodiment, VFR is greater than or equal to about 1V, and Trecov′ is between about 5 μsec and about 10 μsec, although other values may be used.

In this example, an erase operation on block BLK2 is the first operation following the read operation, and includes an erase word line recovery phase and an erase phase. In particular, the erase word line recovery phase is performed with a plurality of blocks selected, so that all word lines in the plurality of blocks are discharged to Vss. In an embodiment, the plurality of blocks may be all blocks. In another embodiment, the plurality of blocks may be all blocks except bad blocks. The word lines are discharged to a voltage VEPR<VFR. In embodiments, word lines may be discharged to a voltage VEPR that is less than about 100 mV, although other values may be used. The erase word line recovery phase occurs during an erase word line recovery time Tprercv, which may be between about 20 μsec and about 100 μsec, although other values may be used.

Following the erase word line recovery phase, the erase phase is performed, with the channel ramping from Vss to Vera. Word line WL0₁ is in block BLK0, and is an unselected word line that is floated during the erase phase. Accordingly, the voltage on word line WL0₁ floats to a value approximately equal to Vera+VEPR. Because VEPR is lower than VFR, the gate-to-drain voltage of the word line switches can be relaxed.

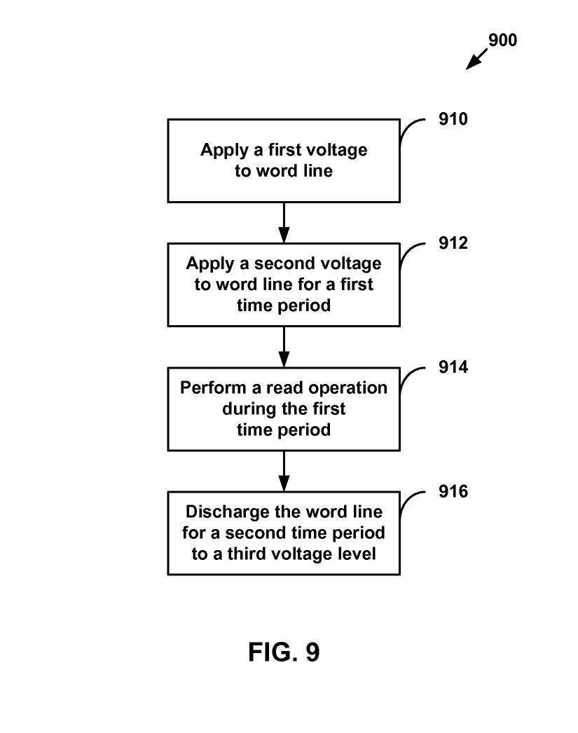

FIG. 9 is a flow chart describing an embodiment of a process 900 for operating a non-volatile storage device. In step 910, a first voltage level (e.g., Vss) is applied to a word line (e.g., WL0₁) connected to a memory cell. In step 912, a second voltage level (e.g., Vread) is applied to the word line for a first time period (e.g., Tvread). In step 914, a read operation is performed on the memory cell during the first time period. In step 916, the word line is discharged during a second time period (e.g., Trecov′) to a third voltage level (e.g., VFR). As described above, in an embodiment, VFR is greater than or equal to about 1V, although other values may be used.

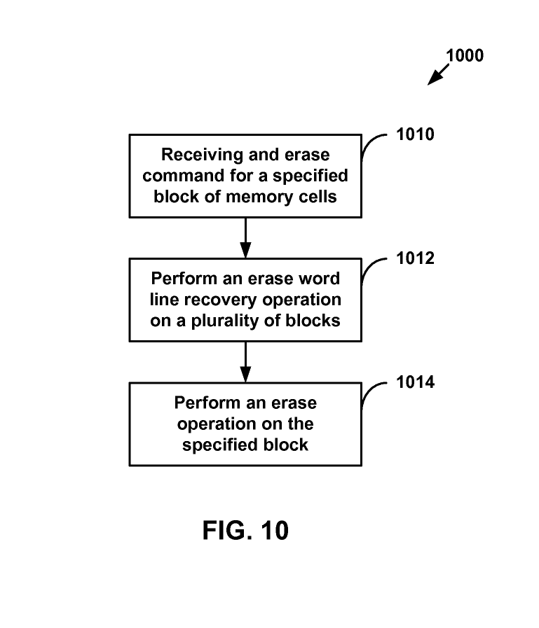

FIG. 10 is a flow chart describing an embodiment of a process 1000 for operating a non-volatile storage device. In step 1010, an erase command is received for a specified block of memory cells (e.g., BLK2) in a memory device. At step 1012, an erase word line recovery operation is performed on a plurality of blocks of memory cells of the memory device. As described above, in an embodiment, the plurality of blocks may be all blocks. In another embodiment, the plurality of blocks may be all blocks except bad blocks. At step 1014, an erase operation is performed on the specified block of memory cells.

One embodiment includes a method for operating non-volatile memory device. The method includes applying a first voltage level to a word line connected to a memory cell, applying a second voltage level to the word line for a first time period, performing a read operation on the memory cell during the first time period, and discharging the word line for a second time period to a third voltage level greater than or equal to about 1V.

One embodiment includes a method for operating non-volatile memory device. The method includes receiving an erase command for a specified block of memory cells in the memory device, performing an erase word line recovery operation on a plurality of blocks of memory cells of the memory device, and performing an erase operation on the specified block of memory cells.

One embodiment includes a non-volatile memory device that includes a word line connected to a memory cell, and a control circuit coupled to the word line. The control circuit applies a first voltage level to the word line, applies a second voltage level to the word line for a first time period, performs a read operation on the memory cell during the first time period, and discharges the word line for a second time period to a third voltage level greater than or equal to about 1V.

For purposes of this document, it should be noted that the dimensions of the various features depicted in the figures may not necessarily be drawn to scale.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more others parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

1. A method for operating non-volatile memory device, the method comprising:
applying a first voltage level to a word line connected to a memory cell;
applying a second voltage level to the word line for a first time period;
performing a read operation on the memory cell during the first time period; and
discharging the word line for a second time period to a third voltage level greater than or equal to about 1V.

2. The method of claim 1, wherein the first voltage level is about 0V.

3. The method of claim 1, wherein the second voltage level is a read pass voltage level.

4. The method of claim 1, wherein the second voltage level is sufficient to turn ON unselected memory cells.

5. The method of claim 1, wherein the second time period is less than a time required to discharge the word line to the first voltage level.

6. The method of claim 1, wherein the non-volatile memory device comprises a 2D non-volatile memory device.

7. The method of claim 1, wherein the non-volatile memory device comprises a 3D stacked non-volatile memory device.

8. A method for operating non-volatile memory device, the method comprising:
receiving an erase command for a specified block of memory cells in the memory device;
performing an erase word line recovery operation on a plurality of blocks of memory cells of the memory device; and
performing an erase operation on the specified block of memory cells.

9. The method of claim 8, wherein the erase word line recovery operation discharges word lines of the plurality of blocks of memory cells to a predetermined voltage level.

10. The method of claim 9, wherein the predetermined voltage level is less than about 100 mV.

11. The method of claim 8, wherein the erase word line recovery operation occurs during a predetermined time period.

12. The method of claim 11, wherein the predetermined time period is sufficient to discharge word lines of the plurality of blocks of memory cells to a predetermined voltage level.

13. The method of claim 8, wherein the non-volatile memory device comprises a 2D non-volatile memory device.

14. The method of claim 8, wherein the non-volatile memory device comprises a 3D stacked non-volatile memory device.

15. A non-volatile memory device comprising:
a word line connected to a memory cell; and
a control circuit coupled to the word line, wherein the control circuit:
applies a first voltage level to the word line;
applies a second voltage level to the word line for a first time period;
performs a read operation on the memory cell during the first time period; and
discharges the word line for a second time period to a third voltage level greater than or equal to about 1V.

16. The non-volatile memory device of claim 15, wherein the first voltage level is about 0V.

17. The non-volatile memory device of claim 15, wherein the second voltage level is a read pass voltage level.

18. The non-volatile memory device of claim 15, wherein the second voltage level is sufficient to turn ON unselected memory cells.

19. The non-volatile memory device of claim 15, wherein the second time period is less than a time required to discharge the word line to the first voltage level.

20. The non-volatile memory device of claim 15, wherein the control circuit:
receives an erase command for a specified block of memory cells in the memory device;
performs an erase word line recovery operation on a plurality of blocks of memory cells of the memory device; and
performs an erase operation on the specified block of memory cells

21. The non-volatile memory device of claim 20, wherein in the erase word line recovery operation, the control circuit discharges word lines of the plurality of blocks of memory cells to a predetermined voltage level.

22. The non-volatile memory device of claim 21, wherein the predetermined voltage level is less than about 100 mV.

23. The non-volatile memory device of claim 20, wherein control circuit performs the erase word line recovery operation during a predetermined time period.

24. The non-volatile memory device of claim 23, wherein the predetermined time period is sufficient to discharge word lines of the plurality of blocks of memory cells to a predetermined voltage level.

25. The non-volatile memory device of claim 15, wherein the non-volatile memory device comprises a 2D non-volatile memory device.

26. The non-volatile memory device of claim 15, wherein the non-volatile memory device comprises a 3D stacked non-volatile memory device.
